(19) United States
(12) Patent Application Publication
(10) Pub. No.: US 2020/0259084 A1
(43) Pub. Date: Aug. 13, 2020

(54) METHOD FOR FORMING OLED ORGANIC THIN FILM LAYERS FOR USING RF SPUTTERING APPARATUS, RF SPUTTERING APPARATUS, AND APPARATUS FOR FORMING TARGET TO BE USED IN RF SPUTTERING APPARATUS

(71) Applicant: Moon Sook SO, Boeun-gun (KR)

(72) Inventor: Moon Sook SO, Boeun-gun (KR)

(21) Appl. No.: 16/637,534

(22) PCT Filed: Oct. 19, 2017
(86) PCT No.: PCT/KR2017/011601

§ 371 Date: Feb. 7, 2020

(30) Foreign Application Priority Data
Aug. 10, 2017 (KR) 10-2017-0101839

(51) Int. Cl. H01L 51/00; H01L 51/56; C23C 14/35; C23C 14/12

(52) U.S. Cl. CPC H01L 51/001; C23C 14/12; C23C 14/35; H01L 51/56

(57) ABSTRACT

Provided is a method for forming a thin film layer of a luminescent organic material for an OLED using an RF sputtering apparatus. The method includes steps of: placing a target comprising a target material for forming a thin film layer of an luminescent organic material for an OLED at a cathode in a chamber of an RF sputtering apparatus and disposing a substrate in which the target material is to be deposited in the chamber; maintaining the chamber in a vacuum state and injecting a reaction gas into the chamber; and applying a minimum RF power and a maximum magnetic field to the target that are sufficient to generate a plasma without damaging the target material.

### CROSS-REFERENCE TO RELATED APPLICATIONS

This application is a national entry of PCT Application No. PCT/KR2017/011601 filed on Oct. 19, 2017, which claims priority to and the benefit of Korean Application No. 10-2017-0101839 filed Aug. 10, 2017, in the Korean Patent Office, the entire contents of which are incorporated herein by reference.

### TECHNICAL FIELD

The present invention relates to a method for forming an OLED, and more particularly, a method of forming an organic thin film layer for an OLED using a sputtering apparatus for organic material deposition, a sputtering apparatus used to perform the method, and an apparatus for forming a target to be used in the RF sputtering apparatus.

### BACKGROUND ART

OLED stands for an active matrix organic light emitting diode. It is one type of EL (electro luminescence) display using a self light-emitting material that emits light when electric current flows. Because the self light-emitting material is used, it does not require a backlight unlike LCDs. Therefore, it has features of realizing a low power consumption, a light weight, and a thin structure.

The structure of an OLED generally includes a plurality of organic thin film layers, as shown in FIG. 1. The OLED organic thin film layers may include a hole injection layer 102, a hole transport layer 103, an light emitting layer 104, an electron transport layer 105, an electron injection layer 106, and a conductor which serves as a cathode 107, including a light-transmitting ITO which serves as an anode 101.

When a DC voltage is applied to the anode 101 and the cathode 107 of the organic thin film layer structure, holes move from the hole injection layer 102 toward the hole transport layer 103, and electrons move through the electron transport layer 105 toward the light emitting layer 104. As the moving holes and electrons meet and combine together in the light emitting layer 104, the energy level of the electrons starts from a stable state and returns to the stable state through a high energy state that is unstable. At this time, light is generated as much as an energy level difference when the electron returns to a stable state from a high energy state.

As a method of depositing an organic material and a metal material to fabricate an OLED, a thermal evaporation method and an E-beam evaporation method are generally used.

FIG. 2 illustrates the concept of a thermal deposition method. In the chamber 110, a crucible 202 containing a raw material 114 to be deposited and a substrate 112 on which the material 114 is to be deposited are disposed. When the crucible 202 is heated to melt the raw material 114, the melted raw material 114 is vaporized and deposited on the upper substrate 112.

FIG. 3 illustrates the concept of an E-beam deposition method. A chamber 120 is depressurized by the vacuum pump 129 to bring the chamber into a vacuum state. Argon (Ar) gas is injected therein through the reaction gas supply unit 128, and the E-beam is irradiated by an E-beam source 127 and at this time the direction of E-beam by the magnetic field is changed so that the E-beam is irradiated to a target 114. The raw material 114 is heated and melted by the directed E-beam and the melted raw material 114 is deposited on the substrate 112 disposed on a upper substrate holder 121.

Meanwhile, as a method of depositing any material on any substrate is a sputtering deposition. According to the sputtering deposition method, activated particles are bombarded onto the target to eject target particles and the ejected target particles are deposited on a substrate. Sputtering can be used for all kinds of targets and substrates because it is a physical method without a chemical or thermal reaction processes. In particular, the RF sputtering deposition method is capable of depositing oxides or insulators at a lower pressure than DC sputtering, and the dispersing of target materials during deposition is relatively weaker than that of DC sputtering. Therefore, it is widely used in the deposition of nonmetallic materials.

Meanwhile, a conventional OLED fabricating method is as follows. First, an anode 101 is formed by depositing ITO on a substrate in a sputtering chamber by a sputtering method. Subsequently, in the thermal deposition chamber or the E-beam deposition chamber, thin films of metallic material such as the hole injection layer 102 and the hole transport layer 103 are formed on the anode 101 using the thermal deposition method or the E-beam deposition method. Next, in another chamber dedicated to deposit organic materials to which a lower temperature than at the time of forming the thin films of the metallic material is applied, the organic material is deposited on the substrate using a thermal evaporation method or an E-beam deposition method to form a light emitting layer 104. Next, in a chamber to which a higher temperature is applied, the metallic materials are deposited by a thermal deposition method or an E-beam deposition method to form an electron transport layer 105 and an electron injection layer 106. Finally, a metal such as aluminum or copper which serves as a cathode is deposited thereon.

As described above, in the conventional OLED fabricating method, since the sputtering method, the thermal deposition method, and the E-beam deposition method are used in a mixed way, a number of chambers having different internal conditions for respective deposition methods are required or several chambers are repeatedly used by changing their internal conditions. Thus, there is a disadvantage in that the cost of constructing the fabricating equipment is high and the fabricating time is long.

In addition, since the thermal evaporation method and the E-beam evaporation method are to heat and evaporate the target material, it is difficult to uniformly control the thickness of films deposited in the center, left and right, and up and down areas as the deposition target area of the substrate grows wider.

Meanwhile, a conventional sputtering method cannot be used in the OLED fabricating method and the reason thereof is as follows:

First, the impact energy applied to the target in the sputtering method is four times higher than the thermal energy applied to the target material in the thermal deposition method or the E-beam deposition method. Application of such high energy to an organic material target causes the organic material to be damaged.

Second, since the impact energy of the target material sputtered from the target, onto the substrate is greatly high and thus it can be damaged during deposition.

Third, the organic material can be damaged by heat occurring at the time of forming the OLED organic material target to be used in the sputtering method. In general, OLED organic materials lose their own properties at temperatures above 200° C. Therefore, if the sputtering target is formed by sintering at a conventional high temperature, the organic material is damaged and its properties are deteriorated. Further, when the organic material is exposed to air during the target forming process, properties of the organic material can be damaged since it combines with oxygen and moisture.

### DETAILED DESCRIPTION OF THE INVENTION

### Technical Problem

The present invention seeks to improve the problems of conventional fabricating methods in which various deposition methods and various chambers are used. That is, by using a sputtering deposition method to deposit not only metallic materials but also organic materials in the OLED fabricating, the present invention is intended to fabricate the OLED using only the sputtering deposition method.

### SUMMARY OF THE INVENTION

According to an embodiment of the invention for achieving the object, a method for forming a thin film layer of a luminescent organic material for an OLED using an RF sputtering apparatus comprises steps of: placing a target comprising a target material for forming a thin film layer of an luminescent organic material for an OLED at a cathode in a chamber of an RF sputtering apparatus and disposing a substrate in which the target material is to be deposited in the chamber; maintaining the chamber in a vacuum state and injecting a reaction gas into the chamber; and applying a minimum RF power and a maximum magnetic field to the target that are sufficient to generate a plasma without damaging the target material.

According to a further embodiment, the magnetic field applied to the target is 1000 to 5000 gauss, and the RF power applied to the target is 0.5 to 10 W/cm². According to a further embodiment, the target is formed by the steps of: preparing a chamber for forming a target; filling the target material into a mold for forming a target in the chamber; maintaining the chamber at a predetermined vacuum degree and heating the mold to a predetermined temperature; pressing the target material filled into the mold at a predetermined pressure; and maintaining the vacuum degree, the temperature and the pressure for a predetermined time. According to a further embodiment, the vacuum degree is 10⁻³ Torr or less; the temperature is 50 to 300° C.; the pressure is 10 to 500 kg/cm²; and the time is greater than or equal to 10 minutes. According to a further embodiment, the forming step further comprises attaching a backing plate on the surface on one side of the formed target. According to a further embodiment, the distance between the target and the substrate is 100 to 200 mm. According to a further embodiment, the reaction gas is injected into the chamber after being cooled by a cooler, and is also injected through a nozzle installed in the vicinity of the target to cool the target.

According to another embodiment of the invention for achieving the object, an RF sputtering apparatus for organic thin film layer formation for OLED comprises: a chamber; a substrate holder for holding a substrate on which a target material is deposited; a target holder on which a target is disposed and in which a magnet for applying a predetermined magnetic field between the target and the substrate is installed, wherein the target includes the target material for forming a thin film layer of the luminescent organic material for OLED; a vacuum pump for maintain the chamber in a vacuum state; a reaction gas supply unit for injecting a predetermined reaction gas into the chamber; and an RF power supply unit for applying a predetermined RF power to the target through the target holder to generate a plasma between the target and the substrate. In particular, the RF power supply unit applies a minimum RF power sufficient to generate a plasma without damaging the target material, and the magnet is controlled to apply a maximum magnetic field that does not damage the target material.

According to a further embodiment, the magnetic field applied to the target by the magnet is 1000 to 5000 gauss, and the RF power applied to the target by the RF power supply unit is 0.5 to 10 W/cm². According to a further embodiment,

According to another embodiment of the invention for achieving the object, an apparatus for forming a target to be used in an RF sputtering apparatus for forming a thin film layer of a luminescent organic material for an OLED comprises: a chamber; a vacuum pump for maintaining the chamber at a predetermined vacuum degree; a mold having a space having a shape of a target to be used in the RF sputtering apparatus; a heater for heating a raw material filled into the space of the mold; a power supply unit for operating the heater; and a press for pressing the raw material to form a thin film layer of the luminescent organic material for OLED filled into the space of the mold at a predetermined pressure.

According to a further embodiment, the vacuum degree is 10⁻³ Torr or less; the temperature for heating the raw material by the heater is 50 to 300° C.; and the pressure pressed by the press is 10 to 500 kg/cm².

### Effect of the Invention

According to the present invention including the above-described configuration, it is possible to form a plurality of metal layers and organic material layers of the OLED using only the sputtering deposition chamber, thereby minimizing the number of chambers and simplifying the fabricating process, This reduces equipment construction costs and reduces fabricating time. In addition, by using the sputtering deposition method, it is possible to uniformly control the film thickness of the target to be deposited, and to apply to a large area. In addition, by optimizing the sputtering conditions, the properties of the organic materials are not impaired.

In addition, since the organic thin film layer of the OLED can be fabricated only by the sputtering deposition method, the sputtering chamber can be arranged in-line to enable continuous operation. As a result, continuous mass production is possible, and continuous production is also possible for any film type product.

### BRIEF DESCRIPTION OF THE FIGURES

FIG. 1 is a view showing a typical organic thin film layer structure of an OLED;

FIG. 2 is a view for explaining a thermal deposition method;

FIG. 3 is a view for explaining an E-beam deposition method;

FIG. 4 is a schematic view for illustrating the configuration of a sputtering apparatus for performing a sputtering deposition method for forming an organic thin film layer according to an embodiment of the present invention;

FIG. 5 is a flowchart showing a method of forming an organic thin film layer using a sputtering apparatus according to the present invention;

FIG. 6 is a schematic view for illustrating the configuration of an apparatus for forming a target to be used in the sputtering apparatus according to the present invention;

FIG. 7 is a flowchart showing a method of forming the target;

FIG. 8 is a diagram illustrating a target form provided;

FIG. 9 is a schematic view for illustrating the configuration of a cathode of the sputtering apparatus according to the present invention;

FIG. 10 shows an in-line fabricating facility using the sputtering deposition method according to the present invention;

FIG. 11 is a TEM photograph showing a state in which an organic material is deposited by a sputtering deposition method according to the present invention; and

FIG. 12 is a photoluminescence (PL) spectrum showing the emission state of the OLED fabricated by the sputtering deposition method according to the present invention.

### DETAILED DESCRIPTION OF THE INVENTION

A sputtering method, in particular an RF sputtering method, which has not been conventionally applied to depositing a light emitting organic material for OLED to form an organic thin film layer, is used for the present invention.

The luminescent organic material for OLED used for the present invention is, for example, Cupc, PTPC, Tiopc, NPB, DTAF, Dpfi-NPB, TAPC, TTP, TFB, DTAA, PEDOT: pis, HMTPD, BCP, TPBC, Tp3pc, BALq, naq, PFNBR, PFN-DoF, TAZ, BTPymB, LiF, ReO3, Moo3, C545T, Alq3, Rubrene. In addition, it may be used, ie. 2T-NATA, HAT-CN, 3TPYMB, TPBi, UGH-2, Fir-6, Ir (bt) 2acac, Ir (ppy) 3, CDBP, mCP, TCTA, Ir (piq) 3, Ir (pq) 2acac, DPVBi, DCJTB, Tp3po, Tp3po, ReO3, TPBA.

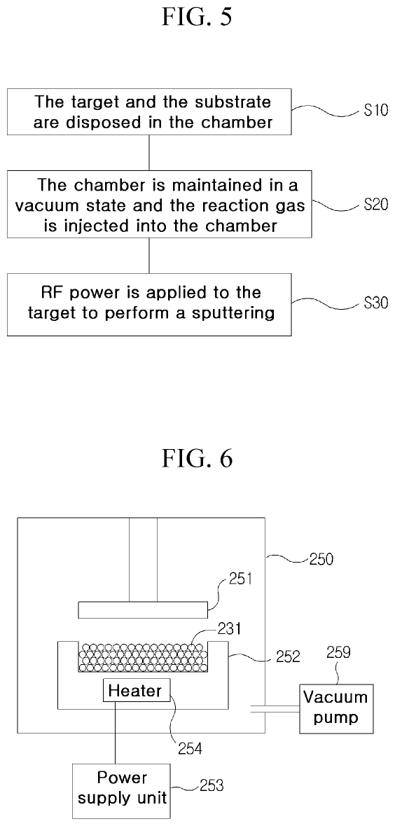

The configuration of a sputtering apparatus used can be understood with reference to FIG. 4. In addition, a method of forming an organic thin film layer that can be performed by the sputtering apparatus can be understood with reference to FIG. 5.

The sputtering apparatus may include a chamber 210, a substrate holder 226, a target holder 236, an RF power supply unit 253, a reaction gas supply unit 214, a cooler 215, and a vacuum pump 219.

At least a substrate 220 and a target 230 may be disposed in the chamber 210, where a sputtering reaction in which the target material is deposited on the substrate 220 occurs.

The substrate holder 226 causes the substrate 220 on which target material is to be deposited, to be positioned within the chamber 210. The substrate holder 226 may secure the substrate 220 using any manner including vacuum or electrostatic adsorption, adhesive or adhesive tape, fastening means.

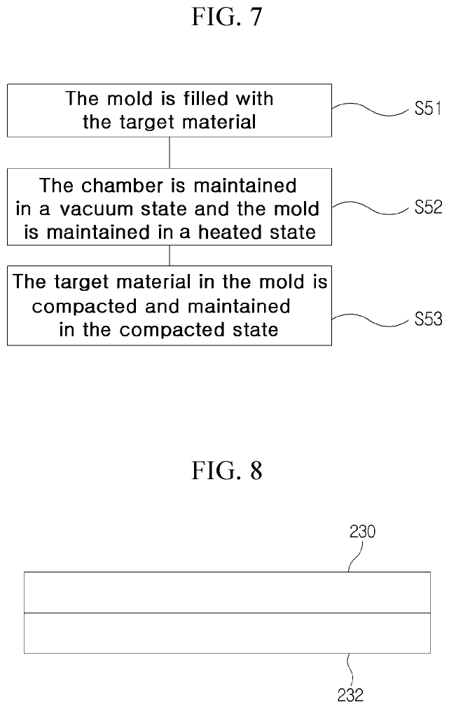

The target holder 236 causes the target 230 to be positioned within the chamber 210, wherein the target 230 is formed by sintering and molding into any shape the target material. The target holder 236 may further include a metal plate 234, a magnet 235, and a shield 239 as shown in detail in FIG. 7. Here, the magnet 235 serves to generate a magnetic field between the target 230 and the substrate 220.

Meanwhile, the target holder 236 itself or the entire structure including the target holder 236 may be referred to as a “cathode”.

The RF power supply unit 253 applies a high frequency power (RF power) to the target 230 through the target holder 236.

The reaction gas supply unit 214 provides a reaction gas for sputter deposition into the chamber 210. The reaction gas may include, for example, argon, hydrogen, nitrogen, fluorine and the like. In addition, the reaction gas may contain oxygen, as necessary.

The cooler 215 cools the reaction gas to be injected into the chamber 210.

The method of forming an organic thin film layer by depositing an organic material for an OLED on a substrate 220 by a sputtering method using such a sputtering apparatus comprises: a step (S10) of preparing a sputtering chamber 210, positioning a substrate on which an organic thin film layer is to be formed, in a substrate holder 226 and positioning a target 230 made of organic material for OLED in a target holder 236; a step (S20) of injecting the reaction gas into the chamber and maintaining the inside of the chamber 210 in a vacuum state; and a step (S30) of applying a magnetic field and an RF power to the target 230. As a result, a plasma is generated between the target 230 and the substrate 220, and a target material sputtered from the target 230 by argon impacting the target 230 is deposited on the substrate 220.

In particular, in conventional method, thin film layer has not been formed by sputtering deposition of an organic material for OLED. However, the present invention allows the deposition of the thin film layer of the organic material for OLED by the sputtering deposition method, by changing various control conditions of the sputtering apparatus. These control conditions are described below:

First, in order to prevent organic material molecules constituting the target 230 from being damaged by physical force in the deposition process, in one embodiment of the present invention, a deposition power (RF power) is reduced to a minimum value. That is, the RF power applied by the RF power supply unit 253 is controlled to a minimum value sufficient to form a plasma (or a minimum value sufficient to cause a sputtering reaction).

In general, the RF sputtering apparatus has a much lower deposition rate than the DC sputtering or the MF sputtering, but has the good dispersion of target material, and is mainly used for the deposition of nonmetallic materials such as SiO₂. Here, in order to improve the deposition rate, the way of raising the RF power (for example, 3-10 W/cm²) has been used in the prior art.

However, if the RF power is continuously increased to improve the deposition rate, a power loss may occur relatively due to the characteristics of the RF power sputtering, and thus a plasma may become unstable. Therefore, while the RF power is increased, a low level of magnetic field is applied to stabilize the plasma state. The best deposition rate appears when the magnetic field is approximately 50 to 700 gauss for a high RF power. However, under conditions of such a high RF power and a low level of magnetic field, when a large number of electrons and Ar (+) ions increased by the high RF power impinge upon a target containing light emitting organic material, strong heat and impact are transmitted to the surface of the target and thus the organic material is damaged.

In contrast, in the present invention, by lowering the RF power to the lowest value possible (lowest value sufficient to cause plasma discharge between the substrate and the target), the minimum number of electrons from the cathode can be emitted. As a result, the number of argon ions colliding with the target 230 can be minimized, thereby minimizing heat generated from the target 230.

Here, in another embodiment of the present invention, the inventor generates magnetic fields of 1,000 to 5,000 gauss at the target 230 such that a plasma can be generated stably even when the lowest RF power, for example, 0.1 to 10 W/cm² is applied. This magnetic field is stronger than that applied in conventional sputter deposition methods. The magnet 235 creating a stronger magnetic field than in the conventional sputtering may be a permanent magnet or an electromagnet.

As such, one of the important features of the present invention is that sputtering apparatus can be used to deposit organic materials for OLEDs. In the present invention a magnetic field of a maximum value is applied while an RF power of a minimum value is applied, unlike conventional sputtering deposition processes.

In addition, in another embodiment according to the present invention, the temperature of the target 230 may be lowered by cooling the reaction gas injected into the chamber 210. For example, a piping from the reaction gas supply unit 214 to the chamber 210 is configured to pass through the cooler 215 filled with liquefied nitrogen, thereby cooling the reaction gas flowing through the piping.

In addition, in the conventional sputtering apparatus, the reaction gas is injected from the bottom surface of the cathode or the rear surface of the substrate holder 226. However, in the present embodiment, the position of the nozzle into which the reaction gas is injected into the chamber 210 is modified such that the cooled reaction gas can flow directly to the surface of the target 230. In this way, since the cooled reaction gas directly cools the surface of the target 230, it is possible to effectively prevent the temperature rise of the target 230. In addition, in this embodiment, in order to prevent oxidation of a target material which is an organic material, a mixed gas may be used by mixing argon with at least one or more of nitrogen, hydrogen, and fluorine in place of oxygen. When OLED organic particles sputtered from the target 230 during operation within the sputtering deposition apparatus, pass through the plasma of nitrogen and/or fluorine gas atmosphere, nitrogen and/or fluorine particles encapsulate the surface of the OLED organic particles and thus the surface exposure of organic materials may be prevented. As a result, the oxidation of organic materials can be prevented.

Further, in another embodiment according to the present invention, in order to reduce the damage caused by the impact energy when the OLED organic particles (ie, target material) sputtered from the target 230 impinge on the substrate 220, a distance (D) between the target 230 and the substrate 220 is larger than that of the prior art. In the present embodiment, the distance D between the target 230 and the substrate 220 may be set to 100 to 200 mm.

Now, with reference to FIG. 6, a configuration of a forming apparatus for forming a target to be used for depositing an OLED organic material by sputtering will be described, and a method for forming a target by the apparatus will be described with reference to FIG. 7.

The apparatus for forming the target 230 to be used in the RF sputtering apparatus for forming a thin film layer of organic material for OLED can form a target 230 by heating/compacting and sintering a raw material 231 to mold a target 230 of a desired shape, wherein the raw material may be in powder form.

A target forming apparatus includes: a chamber 250; a vacuum pump 259 for maintaining the inside of the chamber 250 at a predetermined vacuum degree; a mold 252 having a space corresponding to a shape of a target 230 to be used in the RF sputtering apparatus; a heater 254 for heating the raw material 231 filled into the space of the mold 252; a power supply unit 253 for supplying power for operating the heater 254; and a press 251 for pressing at a predetermined pressure the raw material 231 filled into the space of the mold 252.

Since organic material used in the fabrication of an OLED changes in properties when it exposed to heat of 200° C. or higher, a conventional target forming method consisting in heating, melting and sintering cannot be used.

Therefore, in the present invention, the OLED organic material which is the raw material 231 for forming the target, is filled into the mold 252 disposed within the chamber 250 of the target forming apparatus (S51); the mold 252 is heated as long as the organic material is not damaged and the mold is maintained in the heated state for a predetermined time, with the chamber 250 is decompressed to a vacuum state by operating the vacuum pump 259 (S52); and the heated raw material 231 is maintained for a predetermined time while being compressed by a press (S53). Accordingly, the target 230 is formed by sintering and molding the raw material 231 within the mold 252.

Here, the inside of the chamber 250 is preferably maintained at a vacuum state of 10⁻³ torr or less. In addition, moisture or foreign matters (eg, molecules except for reaction gases) remaining between raw materials filled into the mold 252 may be discharged from spaces between the raw materials as well as the chamber 210 by maintaining the vacuum state for at least 10 minutes.

In addition, by operating the heater 254 by means of the power supply unit 253 to heat the mold 252, as a result, to heat the raw material within the mold, moistures or foreign matter between the raw materials can be rapidly evaporated. Here, in addition to applying the heater 254 to the mold 252, it is also possible to configure the mold itself to generate heat.

When the temperature of the mold 252 reaches, for example, 50 to 150° C. (or after being maintained for a predetermined time after the temperature is reached), all of the moistures and foreign matters remaining in the raw material 231 can be removed. At this time, the raw material 231 within the mold 252 is pressed by operating the press 251. The applying pressure may be 10 to 500 kg/cm². And the state in which pressure is applied is kept for 10 minutes or more, preferably for 60 minutes or more. The target 230 in the shape of the mold 252 is formed through the above steps.

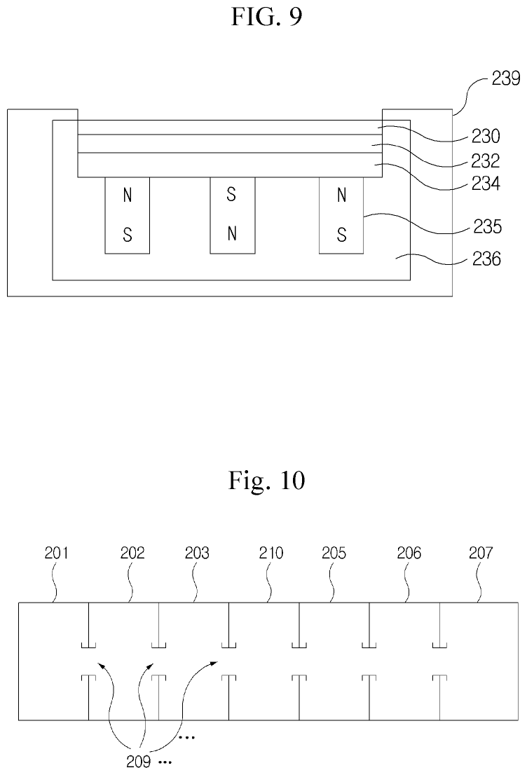

Meanwhile, when forming of the target 230 is completed, the formed organic target 230 may be attached to a backing plate 232 as shown in FIG. 8. The target 230 composed of organic material attached to the backing plate 232 may be fixed to the target holder (or the metallic electrode plate of FIG. 9). The fixing method may include a method of bolting through the backing plate 232, an adhesive or an adhesive tape, a vacuum/electrostatic adsorption, and the like.

Next, with reference to FIG. 9, the structure of a cathode of the sputtering apparatus according to the present invention is illustrated. The cathode includes a target holder 236 to which RF power is applied and on which the target 230 is placed. In addition, the magnet 235 may be disposed in the target holder 236 to generate a magnetic field between the disposed target 230 and the substrate 220. Here, an electrode plate 234 composed of a conductive metallic material such as copper may be disposed at a portion which is in contact with the target (or the backing plate of the target).

In addition, a shield 239 may be formed around the target holder 236 to prevent an exposure of the portions other than the target 230 to the outside or to minimize the exposure.

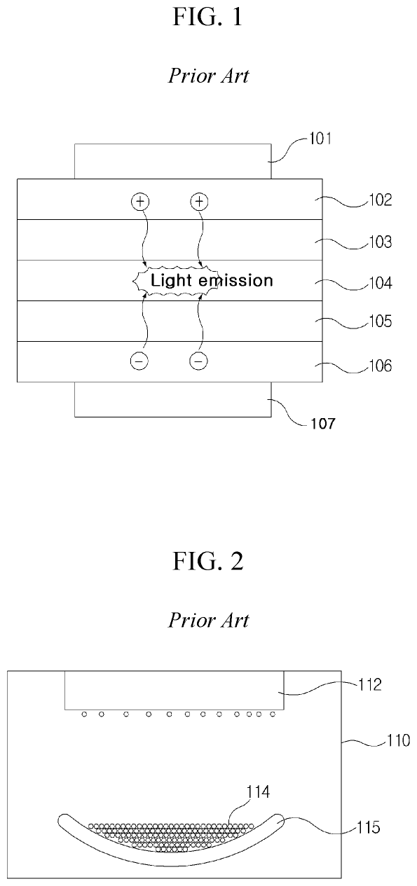

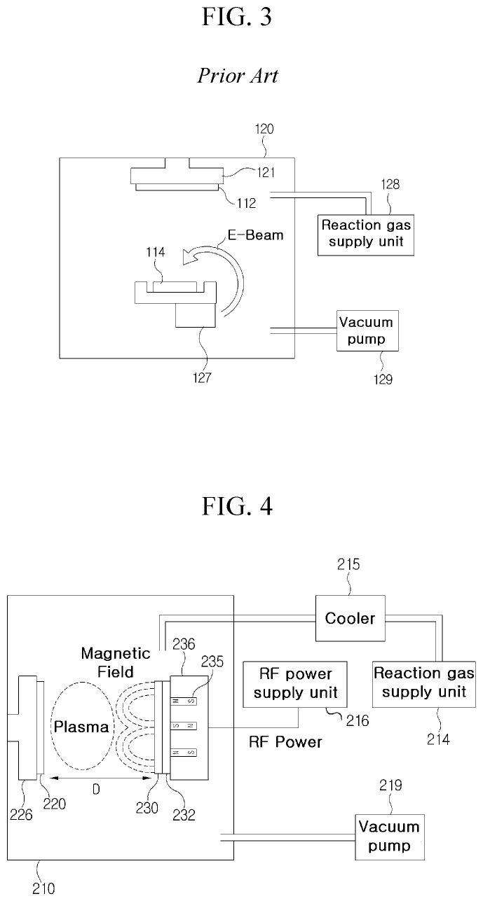

A plurality of sputtering apparatuses, each of which has the above-described configuration and method, may be arranged in-line to form a plurality of thin film layers in a continuous process. That is, since the sputtering deposition method can be used to form each layer of the plurality of thin film layers as shown in FIG. 1, the plurality of sputtering apparatuses all can be connected and integrated in a continuous process.

FIG. 10 illustrates that a chamber 201 for depositing the hole injection layer 102 by the sputtering method, a chamber 202 for depositing the hole transport layer 103 by the sputtering method, and a chamber for depositing the light emitting layer 104 by the sputtering method 210, a chamber 206 for depositing the electron transport layer 105 by the sputtering method, and a chamber 207 for depositing the electron injection layer 106 by the sputtering method are connected in a line.

The respective chambers can be connected to a product transport passage 209.

By connecting the plurality of chambers in a line and configuring the product transport passage 209, various thin film layers can be deposited in a continuous process. Therefore, the fabricating speed is fast and the mass production is feasible. In addition, since the substrate 220 having the target material deposited thereon is moveable, the continuous operation can be performed in an in-line sheet-to-sheet processing and a roll-to-roll processing of films.

Here, between the chamber 202 and the chamber 210 and between the chamber 206 and the chamber 210 wherein target materials are changed therebetween, buffer chambers 203 and 205 for preventing the movement of the materials can be arranged, respectively. These buffer chambers 203 and 205 can be configured with empty spaces, thereby minimizing the migration of reaction gases and target materials leaking from adjacent chambers to other adjacent chambers on the opposite side.

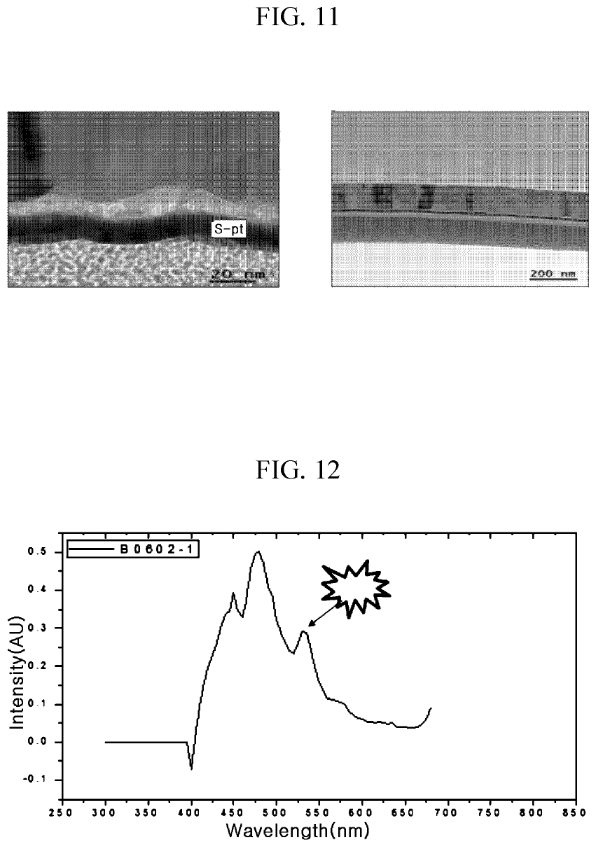

FIG. 11 is a TEM photograph showing a state where the organic materials are deposited under the sputtering apparatus and the control conditions according to the above-described configuration. On the left side of the photograph, it can be seen that the organic material is damaged when the organic material is deposited using the conventional sputtering apparatus and sputtering method as they are. Meanwhile, on the right side of the photograph, an organic material layer 901 deposited with a uniform thickness fabricated by the sputtering method according to the present invention and an ITO layer 902 deposited with a uniform thickness thereon can be seen.

Next, FIG. 12 is a PL spectrum showing the light emission state of the OLED fabricated by the sputtering deposition method according to the present invention. In the figure, it can be seen that the organic material deposited without damage by the sputtering method according to the present invention exhibits desirable luminescence properties.

What is claimed is:

1. A method for forming a thin film layer of a luminescent organic material for an OLED using an RF sputtering apparatus, comprising steps of:
placing a target comprising a target material for forming a thin film layer of an luminescent organic material for an OLED at a cathode in a chamber of an RF sputtering apparatus and disposing a substrate in which the target material is to be deposited in the chamber;
maintaining the chamber in a vacuum state and injecting a reaction gas into the chamber; and
applying a minimum RF power and a maximum magnetic field to the target that are sufficient to generate a plasma without damaging the target material.

2. The method of claim 1, wherein the magnetic field applied to the target is 1000 to 5000 gauss, and the RF power applied to the target is 0.5 to 10 W/cm².

3. The method of claim 1, wherein the target is formed by the steps of:
preparing a chamber for forming a target;
filling the target material into a mold for forming a target in the chamber;
maintaining the chamber at a predetermined vacuum degree and heating the mold to a predetermined temperature;
pressing the target material filled into the mold at a predetermined pressure; and
maintaining the vacuum degree, the temperature and the pressure for a predetermined time.

4. The method of claim 3, wherein the vacuum degree is 10⁻³ Torr or less;
the temperature is 50 to 300° C.;
the pressure is 10 to 500 kg/cm²; and
the time is greater than or equal to 10 minutes.

5. The method of claim 3, wherein the forming step, further comprises attaching a backing plate on the surface on one side of the formed target.

6. The method of claim 1, wherein the distance between the target and the substrate is 100 to 200 mm.

7. The method of claim 1, wherein the reaction gas is injected into the chamber after being cooled by a cooler, and is also injected through a nozzle installed in the vicinity of the target to cool the target.

8. An RF sputtering apparatus for organic thin film layer formation for OLED comprising:
a chamber;
a substrate holder for holding a substrate on which a target material is deposited;
a target holder on which a target is disposed and in which a magnet for applying a predetermined magnetic field between the target and the substrate is installed, wherein the target includes the target material for forming a thin film layer of the luminescent organic material for OLED;
a vacuum pump for maintain the chamber in a vacuum state;
a reaction gas supply unit for injecting a predetermined reaction gas into the chamber; and
an RF power supply unit for applying a predetermined RF power to the target through the target holder to generate a plasma between the target and the substrate;
wherein the RF power supply unit applies a minimum RF power sufficient to generate a plasma without damaging the target material, and wherein the magnet is controlled to apply a maximum magnetic field that does not damage the target material.

9. The apparatus of claim 8, wherein the magnetic field applied to the target by the magnet is 1000 to 5000 gauss, and the RF power applied to the target by the RF power supply unit is 0.5 to 10 W/cm².

10. An apparatus for forming a target to be used in an RF sputtering apparatus for forming a thin film layer of a luminescent organic material for an OLED comprising:
a chamber;
a vacuum pump for maintaining the chamber at a predetermined vacuum degree;
a mold having a space having a shape of a target to be used in the RF sputtering apparatus;
a heater for heating a raw material filled into the space of the mold;
a power supply unit for operating the heater; and
a press for pressing the raw material to form a thin film layer of the luminescent organic material for OLED filled into the space of the mold at a predetermined pressure.

11. An apparatus of claim 10, wherein the vacuum degree is 10⁻³ Torr or less; the temperature for heating the raw material by the heater is 50 to 300° C.; and the pressure pressed by the press is 10 to 500 kg/cm².
